(19) United States
(12) Patent Application Publication
(10) Pub. No.: US 2013/0043579 A1
(43) Pub. Date: Feb. 21, 2013

(54) POWER SEMICONDUCTOR ARRANGEMENT, POWER SEMICONDUCTOR MODULE WITH MULTIPLE POWER SEMICONDUCTOR ARRANGEMENTS, AND MODULE ASSEMBLY COMPRISING MULTIPLE POWER SEMICONDUCTOR MODULES

(71) Applicant: Franc DUGAL, Zollikon (CH)

(72) Inventor: Franc DUGAL, Zollikon (CH)

(73) Assignee: ABB TECHNOLOGY AG, Zurich (CH)

(21) Appl. No.: 13/588,727

(22) Filed: Aug. 17, 2012

(30) Foreign Application Priority Data
Aug. 17, 2011 (EP) 11177801.5

(51) Int. Cl. H01L 23/06

(52) U.S. Cl. 257/690; 257/E23.191

(57) ABSTRACT

A power semiconductor arrangement includes a base plate having a molybdenum layer, and a power semiconductor device mounted to a top side of the base plate and electrically and thermally coupled thereto. The base plate includes a metallic mounting base, which is arranged between the semiconductor device and the molybdenum layer and prevents the molybdenum layer from forming highly resistive intermetallic phases with the semiconductor device. A semiconductor module, such as a power semiconductor module, includes multiple semiconductor arrangements, whereby the base plate of the semiconductor arrangements is a common base plate. A module assembly, such as a power semiconductor module assembly, includes multiple semiconductor modules, whereby the semiconductor modules are arranged side by side to each other with electric connections between adjacent semiconductor modules.

### RELATED APPLICATION

This application claims priority under 35 U.S.C. §119 to European Patent Application No. 11177801.5 filed in Europe on Aug. 17, 2011, the entire content of which is hereby incorporated by reference in its entirety.

### FIELD

The present disclosure relates to a power semiconductor arrangement, which includes a base plate having a molybdenum layer, and a power semiconductor device mounted to a top side of the base plate and electrically and thermally coupled thereto. The present disclosure also relates to a power semiconductor module with multiple power semiconductor arrangements. The present disclosure also relates to a module assembly, such as a power semiconductor module assembly, including multiple power semiconductor modules.

### BACKGROUND INFORMATION

Power semiconductor arrangements of the aforementioned kind are known in the art and are used, for example, in the area of mounting and contacting power semiconductor devices as well as high power semiconductors. These power semiconductors devices may deal with voltages of about 1.7 kV or higher and are mounted to the base plate by means of bonding, soldering or others. The base plate in these power semiconductor arrangements is in surface contact with one side of the power semiconductor device, so that current can be provided from the base plate directly to the power semiconductor device. The surface contact between the power semiconductor device and the base plate enables heat transfer away from the power semiconductor. In order to keep the power semiconductor device at a desired working temperature, coolers can be connected to the base plate as heat sinks. Accordingly, the power semiconductor device is thermally and electrically coupled to the base plate. Known power semiconductor devices used in this area are insulated gate bipolar transistors (IGBT), reverse conducting insulated gate bipolar transistors (reverse conducting IGBT), bi-mode insulated gate transistors (BIGT) or (power) diodes.

Such power semiconductor arrangements are frequently combined, for example, for forming a power semiconductor module, which can deal with currents of up to 100 A and higher. The power semiconductor arrangements are arranged in parallel on a common base plate, which may form an electrically conducting base of the power semiconductor module. The power semiconductor module may be covered by an electrically conducting lid, which provides a further contact for the power semiconductor devices. The power semiconductor devices may be connected to the electrically conducting lid by means of presspins, which are known in the art.

A presspin includes a foot and a head, which are movable relative to each other along a longitudinal axis of the presspin and which are electrically interconnected, for example, by a current bypass. Between the foot and the head a spring element is arranged, which exerts an outwardly directed force on the foot and the head for pushing them against contact elements of the power semiconductor devices and opposed contacts, for example, a lid of a housing, to maintain electric connection there between. The spring element may be a spring washer pack, but other spring elements may be used as well. The contact between the foot and the respective contact element is provided via a base of the foot. Such presspins are used to contact gate or control contacts, collector contacts and/or emitter contacts.

Multiple power semiconductor modules can further be combined to form a module assembly, such as a power semiconductor module assembly. The power semiconductor modules are arranged side by side to each other with electric connections between adjacent power semiconductor modules. The module assembly can include identical power semiconductor modules, for example, semiconductor modules including power transistors, or different power semiconductor modules, for example, a set of semiconductor modules including power transistors and at least one semiconductor module including power diodes. Such module assemblies are known, for example, as “Stakpak” from the applicant and can be used for forming stacked arrangements as used, for example, in HVDC applications. Accordingly, the mechanical design of the module assembly is optimized in order to facilitate clamping in long stacks.

In such power semiconductor modules and power module assemblies, there should be support of a short circuit failure mode (SCFM) of the individual power semiconductor devices. In case one of the power semiconductor devices fails, it fails by providing a short circuit to enable conduction from the base plate to the lid. Accordingly, when multiple of the power semiconductor modules or the module assemblies are connected in series, for example, forming a stack, failure of a single power semiconductor device does not lead to a failure of the series of the power semiconductor modules or the module assemblies.

In this short circuit failure mode, very high currents can flow through a single power semiconductor device, since the short circuit disables all parallel power semiconductor devices. To achieve a high life time of these power semiconductor devices and accordingly a high life time of the power semiconductor modules and the module assemblies, it is desired that the short circuit failure mode can be maintained for a year or even more, for example. Accordingly, the contact of the power semiconductor and the base plate should be able to deal for a prolonged time with substantial heat due to the short circuit current. To provide good conduction in short circuit failure mode, it is known to provide a small platelet containing aluminum over the semiconductor device. When the power semiconductor device fails and the short circuit current raises the temperature, the aluminum melts and forms an alloy with the silicon of the power semiconductor device. This AlSi alloy has a relatively good electrical and thermal conduction. Nevertheless, aging of the contact between the base plate and the failed power semiconductor device can increase electrical resistance up to a point that it is high enough to break another power semiconductor device, so that the problem is propagated through the entire power semiconductor module and the entire module assembly. In the area of power and high power semiconductors, this is of concern, since large amounts of energy are present and arcing can occur within the power semiconductor module. Worst case, even neighbouring cooler damages can occur or a failure of the entire system.

Investigation has shown that a main reason for electric contact aging and failure is the formation of particularly two highly resistive intermetallic phases between the semiconductor device and the base plate. The term “highly resistive” refers to the resistance compared to a “normal” resistance of a contact between the power semiconductor device and the base plate, for example, when AlSi is formed at the contact in SCFM. These phases are generally Mo(SiAl)₂ and MoSi₂, which reduce the electrical and thermal conductivity between the power semiconductor device and the base plate. Accordingly, the contact temperature increases and the SCFM life time is reduced.

Intents to use a base plate made of pure copper or pure aluminium have resulted in an increased life time of the power semiconductor arrangement, such as in a short circuit failure mode, since the formation of the above-mentioned intermetallic phases is prevented. Nevertheless, the use of these base plates resulted in drawbacks due to the different coefficient of thermal expansion of aluminium or copper as compared to silicon. Changes in the temperature of the power semiconductor arrangement result in shearing forces at the connection between the power semiconductor device and the base plate, so that the stability of the connection between the power semiconductor device and the base plate is reduced over the time. This limits the thermal cycling capacity, which is a drawback in the area of semiconductor devices, such as power semiconductor devices.

Another drawback occurring in these power semiconductor arrangements is the issue of overheating of the power semiconductor device and heat transfer away from the semiconductor device. In power semiconductor devices, it is desired to provide a reliable cooling mechanism, so that the semiconductor device can be operated at a desired working temperature or at least below a maximum temperature. Cooling is frequently realized by heat transfer from the semiconductor device to the base plate, which further transfers the heat to a cooling mechanism, for example, a cooler attached thereto. The heat transfer away from the semiconductor device is a limiting factor in chip design, for example, when referring to power semiconductor devices. Accordingly, improvements are also required in this area.

### SUMMARY

An exemplary embodiment of the present disclosure provides a power semiconductor arrangement which includes a base plate having a molybdenum layer. The exemplary power semiconductor arrangement also includes a power semiconductor device mounted to a top side of the base plate and electrically and thermally coupled thereto. In addition, the exemplary power semiconductor arrangement includes a presspin which is arranged next to the power semiconductor device on the opposite side of the base plate. The base plate includes a metallic mounting base, which is arranged between the semiconductor device and the molybdenum layer and is configured to prevent the molybdenum layer from forming highly resistive intermetallic phases with the semiconductor device.

### BRIEF DESCRIPTION OF THE DRAWINGS

Additional refinements, advantages and features of the present disclosure are described in more detail below with reference to exemplary embodiments illustrated in the drawing, in which:

FIG. 1 shows a sectional view of a power semiconductor arrangement of a power semiconductor module with multiple power semiconductor arrangements according to an exemplary embodiment of the present disclosure, whereby a power semiconductor device of the power semiconductor arrangement is contacted by a press pin.

### DETAILED DESCRIPTION

Exemplary embodiments of the present disclosure provide a power semiconductor arrangement, a power semiconductor module with multiple power semiconductor arrangements, and a module assembly including multiple power semiconductor modules, which have a long lifetime of the electrical and thermal connection between the power semiconductor device and the base plate and provide good heat transfer away from the power semiconductor device, such as in a short circuit failure mode.

An exemplary embodiment of the present disclosure provides a power semiconductor arrangement, which includes a base plate having a molybdenum layer, and a power semiconductor device mounted to a top side of the base plate and electrically and thermally coupled thereto. The base plate includes a metallic mounting base, which is arranged between the semiconductor device and the molybdenum layer and prevents the molybdenum layer from forming highly resistive intermetallic phases with the semiconductor device. Further, a presspin is arranged next to the power semiconductor device on the opposite side of the base plate.

An underlying feature of the present disclosure provides an intermediate mounting base between the power semiconductor device and the molybdenum layer, so that the silicon of the power semiconductor device and the molybdenum of the molybdenum layer cannot form highly resistive intermetallic phases, such as Mo(SiAl)₂ and MoSi₂. The use of a metallic material maintains electric and thermal conductivity, so that the normal operation of the power semiconductor arrangement is not limited. In accordance with an exemplary embodiment, metallic materials having a good conductivity for current and heat are utilized. The coefficient of thermal expansion of the molybdenum of the molybdenum layer limits problems also provides a suitable thermal cycling capacity.

An exemplary embodiment of the present disclosure also provides a power semiconductor module with multiple semiconductor arrangements as described above, whereby the base plate of the power semiconductor arrangements is a common base plate. Accordingly, a single base plate can be used as a basis for mounting several power semiconductor devices thereon, for example, in a parallel manner, so that the power semiconductor module is easy to handle. Multiple power semiconductor devices can be contacted easily by merely contacting the common base plate of the power semiconductor module.

An exemplary embodiment of the present disclosure also provides a module assembly, such as a power semiconductor module assembly, which includes multiple power semiconductor modules as described above, whereby the power semiconductor modules are arranged side by side to each other with electric connections between adjacent semiconductor modules. Multiple module assemblies can be contacted easily by merely contacting the module assembly. The module assembly can include identical semiconductor modules, for example, semiconductor modules including power transistors like insulated gate bipolar transistors (IGBT), reverse conducting insulated gate bipolar transistors (reverse conducting IGBT) or bi-mode insulated gate transistors (BIGT), or different power semiconductor modules, for example, a set of power semiconductor modules including power transistors and at least one power semiconductor module including power diodes. Such module assemblies can be used for forming stacked arrangements as used for example in HVDC applications.

According to an exemplary embodiment of the present disclosure, the mounting base is made of copper. In other exemplary embodiments of the present disclosure, the mounting base is made of an alloy based on copper. Since copper shows a good thermal and electric conductivity, it is suitable to be used without limiting the operation of the power semiconductor arrangement. This also applies to alloys based on copper, especially to alloys having similar characteristics like copper in respect to electrical and thermal conduction. Alloys additionally containing silver may also be utilized.

According to an exemplary embodiment of the present disclosure, the mounting base supports the formation of a short-circuit failure mode in case of the failure of the power semiconductor device.

According to an exemplary embodiment of the present disclosure, a platelet is arranged between the power semiconductor device and the presspin. The platelet may be made of copper, aluminum, silver, gold and/or an alloy thereof. The platelet may help to form the short circuit failure mode.

According to an exemplary embodiment of the present disclosure, the mounting base is provided as a mounting plate with a surface area bigger than the surface area of the power semiconductor device. The increased size of the mounting base compared to the size of the power semiconductor device improves the cooling of the power semiconductor, since heat can be dissipated via the mounting plate and then be transferred to the molybdenum layer of the base plate. Heat transfer characteristics of copper or copper based alloys are usually better than heat transfer characteristics of molybdenum. Accordingly, the performance of the power semiconductor device can be improved due to improved cooling.

According to an exemplary embodiment of the present disclosure, the mounting base is provided as a mounting layer extending over the molybdenum layer. This facilitates the production of the base plate, since the mounting base can be applied in a single production process over the entire surface of the molybdenum layer. Also, base plates can be provided without having to deal with a particular design of a power semiconductor arrangement. Accordingly, mass production can be performed at low costs.

According to an exemplary embodiment of the present disclosure, the mounting layer is laminated to the molybdenum layer. Laminating is a manufacturing process, which can be performed easily and rapidly and therefore allows of the provisioning of base plates at low manufacturing costs. Nevertheless, other process steps can also be applied for connecting the molybdenum layer and the mounting layer, for example, bonding, or soldering.

According to an exemplary embodiment of the disclosure, the base plate includes a base layer, which is provided on the molybdenum layer opposite to the mounting layer, whereby the base layer has a thermal expansion coefficient essentially equal to the thermal expansion coefficient of the mounting layer. The base layer allows for the base plate to have a sandwich structure, which prevents bending due to different thermal expansion coefficients of the materials of the molybdenum layer and the mounting layer. The base layer provides a bending force in a direction opposite to the bending force of the mounting layer, so that the base plate remains in a planar shape, even when it undergoes temperature changes. This allows the use of big base plates without the danger of bending. Additionally, the base layer improves cooling of the power semiconductor, especially when the thermal coefficient of the material of the base layer is higher than the thermal coefficient of the molybdenum layer. Accordingly, heat dissipation and transfer of the base plate can be improved.

According to an exemplary embodiment, the base layer and the mounting layer are provided as identical layers. The base plate can be easily manufactured, since only one material has to be provided for the base layer and the mounting layer, which can be processed by a single processing step. The use of identical layers also provides the base plate with a uniform sandwich structure, which further reduces the possibilities of bending due to thermal expansion of different materials of the base layer and the mounting layer one the one hand-side and the molybdenum layer on the other hand-side.

According to an exemplary embodiment of the present disclosure, the thickness of the molybdenum layer is at least 3 times higher than the thickness of the mounting plate or mounting layer. For example, the thickness of the molybdenum layer can be 3 to 10 times higher, such as 5 to 6 times higher than the thickness of the mounting plate or mounting layer. This thickness relation has shown good performance in practical tests. First, a good cycling capacity is achieved despite the different thermal expansion of the materials of the mounting plate/layer and the molybdenum layer. Second, a good heat transfer and dissipation from the power semiconductor to the molybdenum layer is achieved. In absolute values, a thickness of the mounting layers of 0.2 mm is an example for a suitable value. In case a base layer is connected to the molybdenum layer, the thickness relation between the mounting plate/mounting layer, the molybdenum layer and the base layer may be 1:3:1 to 1:10:1, such as 1:5:1 to 1:6:1, thereby forming a uniform sandwich structure of the base plate. Since the thickness of the mounting plate/mounting layer and the base layer is equal, bending due to thermal expansion of the different materials can be avoided.

According to an exemplary embodiment of the present disclosure, the thickness of the molybdenum layer is between 1 mm and 10 mm. Such a thickness of the molybdenum layer provides a good stability of the base plate. Also good heat transfer away from the power semiconductor device can be achieved.

According to an exemplary embodiment of the power semiconductor module of the present disclosure, the power semiconductor module includes a housing, whereby an electrically conducting lid forms a top side of the housing and provides a first contact of the power semiconductor module, the common base plate forms a base of the housing and provides a second contact of the power semiconductor module, and the power semiconductor devices are in electric contact with the lid. In accordance with an exemplary embodiment, presspins are provided between the power semiconductor devices and the lid for providing the electrical contact. Generally speaking, the lid provides a first contact of the power semiconductor module for contacting first contacts of the power semiconductor devices, and the base plate provides a second contact of the power semiconductor module for contacting second contacts of the semiconductor devices. When power transistors are used as power semiconductor devices, the base plate may be connected to the collector of the power transistors, and the emitter of the power transistors may be connected to the lid. The gates of the power transistors are also commonly connected within the power semiconductor module, and can be contacted, for example, through a spare in the lid or by a lateral contact.

According to an exemplary embodiment of the module assembly of the present disclosure, the base plates of the power semiconductor modules are electrically connected to each other. The connection can be made by wiring or by providing a contact plate for contacting the base plates of the power semiconductor modules.

According to an exemplary embodiment of the module assembly of the present disclosure, the module assembly includes a housing, whereby the common base plates of the power semiconductor modules extend through a base of the housing, and an electrically conducting lid forms a top side of the housing and provides a common contact for the power semiconductor modules. Generally speaking, the lid provides a first contact of the module assembly for contacting the first contacts of the semiconductor modules, and the base plate provides a second contact of the module assembly for contacting the second contacts of the power semiconductor modules. The gate contacts of the power semiconductor modules are also commonly contacted in the module assembly and are connected to a lateral contact of the module assembly or can be contacted through a spare in the lid.

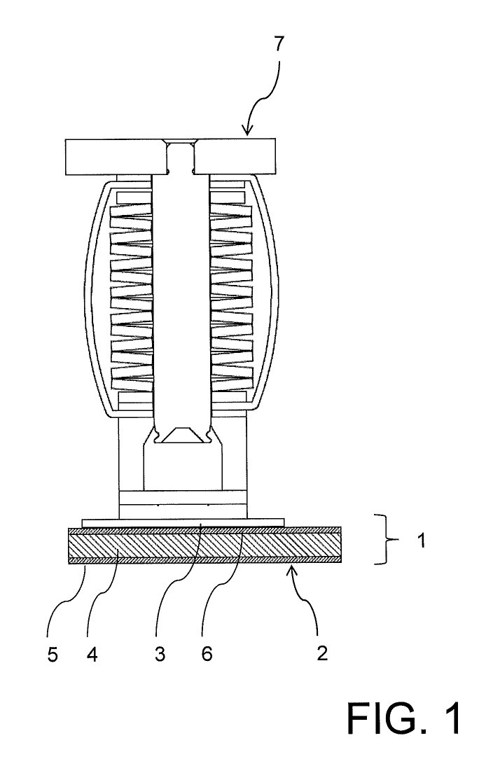

FIG. 1 shows a power semiconductor arrangement 1 according to an exemplary embodiment of the present disclosure. The power semiconductor arrangement 1 includes a base plate 2 and a power semiconductor device 3. The base plate 2 is a laminated plate including a central molybdenum layer 4, which is sandwiched between a base layer 5 and a mounting layer 6. The thickness of the molybdenum layer 4 according to this exemplary embodiment of the present disclosure is approximately 5 mm.

The power semiconductor device 3 in this exemplary embodiment of the present disclosure is a power power semiconductor device, for example, an IGBT, and can be used for voltages up to 1.7 kV or higher. It is mounted on a top side of the mounting layer 6 and thereby electrically and thermally coupled thereto. The power semiconductor device 3 is contacted on its upper side, which lies opposite to the base plate 2, by a presspin 7. Since presspins 7 are known, further details in respect to the presspin 7 are not given here. The mounting layer 6 serves as mounting base for the power semiconductor 3, whereby the extension of the mounting layer 6 is bigger than the surface area of the power semiconductor.

In accordance with an exemplary embodiment, the mounting layer 6 and the base layer 5 are both made of copper and are laminated to the molybdenum layer 4. The thickness of the mounting layer 6 and the base layer 5 is 1 mm in this exemplary embodiment of the present disclosure. Accordingly, the thickness relation between the mounting layer 6, the molybdenum layer 4 and the base layer 5 is 1:5:1 in this exemplary embodiment of the present disclosure. The base layer 5 and the mounting layer 6 extend over the entire surface of the molybdenum layer 4 on the respective side thereof. Accordingly, the layers 5, 6 are equally provided on both sides of the molybdenum layer 4 and the thermal expansion of the layers 5, 6 compensates each other. Therefore, even in thermal cycles involving heating and/or cooling, the base plate 2 remains in a planar shape.

Since the base plate 2 is provided with the mounting layer 6 on the top side of the molybdenum layer 4, the power semiconductor device 3 and the molybdenum layer 4 are not in direct contact. Accordingly, the formation of intermetallic phases, such as Mo(SiAl)₂ and MoSi₂, between the molybdenum of the molybdenum layer 4 and the silicon of the power semiconductor device 3 is reliably prevented.

The power semiconductor arrangement 1 of FIG. 1 forms part of a power semiconductor module, which includes multiple power semiconductor arrangements 1 as described above. The base plate 2 of the power semiconductor arrangements 1 is a common base plate 2, on which all power semiconductors devices 3 are mounted. In this exemplary embodiment of the present disclosure, the multiple power semiconductor devices 3 are arranged in parallel to each other on the base plate 2 and form a power semiconductor module.

The power semiconductor module includes a housing, whereby the common base plate 2 forms a base of the housing. An electrically conducting lid forms a top side of the housing. The lid provides a first contact of the power semiconductor module, and the base plate 2 provides a second contact of the power semiconductor module. The power semiconductor devices 3 are in electric contact with the lid by means of presspins 7, which are provided between the power semiconductor devices and the lid for providing electrical contact there between. The base plate 2 is connected to the collectors of the power semiconductor devices 3, and the emitters of the power semiconductor devices 3 are connected to the lid. The gates of the power semiconductor devices 3 are also commonly contacted in the power semiconductor module through a spare in the lid.

A power semiconductor module assembly includes multiple power semiconductor modules as described above. The power semiconductor modules are arranged side by side to each other within a housing, whereby the common base plates 2 of the power semiconductor modules extend through a base of the housing. An electrically conducting lid forms a top side of the housing and provides a common contact for the power semiconductor modules with electric connections between adjacent semiconductor modules. The lid provides a first contact of the module assembly for contacting the first contacts of the power semiconductor modules, and the base plate provides a second contact of the module assembly for contacting the second contacts of the power semiconductor modules. The gate contacts of the power semiconductor modules are connected to each other within the module assembly and are connected to a lateral contact of the module assembly.

The module assembly includes different power semiconductor modules, in this exemplary embodiment of the disclosure a set of power semiconductor modules including power transistors and at least one power semiconductor module including power diodes. The module assembly is used for forming a stacked arrangement in a HVDC application.

While the present disclosure has been illustrated and described in detail in the drawings and foregoing description, such illustration and description are to be considered illustrative or exemplary and not restrictive; the disclosure is not limited to the disclosed embodiments. Other variations to be disclosed embodiments can be understood and effected by those skilled in the art in practicing the claimed disclosure, from a study of the drawings, the disclosure, and the appended claims. In the claims, the word “comprising” or “including” does not exclude other elements or steps, and the indefinite article “a” or “an” does not exclude a plurality. The mere fact that certain measures are recited in mutually different dependent claims does not indicate that a combination of these measures cannot be used to advantage.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE SIGNS LIST

1 Power semiconductor arrangement
2 base plate
3 power semiconductor device
4 molybdenum layer
5 base layer
6 mounting layer
7 presspin

What is claimed is:

1. A power semiconductor arrangement, comprising
a base plate having a molybdenum layer;
a power semiconductor device mounted to a top side of the base plate and electrically and thermally coupled thereto; and
a presspin which is arranged next to the power semiconductor device on the opposite side of the base plate,
wherein the base plate includes a metallic mounting base, which is arranged between the semiconductor device and the molybdenum layer and is configured to prevent the molybdenum layer from forming highly resistive intermetallic phases with the semiconductor device.

2. The semiconductor arrangement according to claim 1, wherein the mounting base is made of copper.

3. The semiconductor arrangement according to claim 1, wherein the mounting base is made of an alloy based on copper.

4. The semiconductor arrangement according to claim 1, wherein the mounting base supports the formation of a short-circuit failure mode in case of failure of the power semiconductor device.

5. The semiconductor arrangement according to claim 1, comprising:
a platelet arranged between the power semiconductor device and the presspin,
wherein the platelet is made of at least one of copper, aluminum, silver, gold magnesium, and an alloy thereof.

6. The semiconductor arrangement according to claim 1, wherein the mounting base is provided as a mounting plate with a surface area bigger than the surface area of the semiconductor device.

7. The semiconductor arrangement according to claim 1, wherein the mounting base is provided as a mounting layer extending over the molybdenum layer.

8. The semiconductor arrangement according to claim 7, wherein the mounting layer is laminated to the molybdenum layer.

9. The semiconductor arrangement according to claim 7, wherein the base plate comprises a base layer, which is provided on the molybdenum layer opposite to the mounting layer, and
wherein the base layer has a thermal expansion coefficient essentially equal to the thermal expansion coefficient of the mounting layer.

10. The semiconductor arrangement according to claim 9, wherein the base layer and the mounting layer are provided as identical layers.

11. The semiconductor arrangement according to claim 6, wherein the thickness of the molybdenum layer is at least 3 times higher than the thickness of the mounting plate.

12. The semiconductor arrangement according to claim 6, wherein the thickness of the molybdenum layer is between 1 mm and 10 mm.

13. A power semiconductor module with multiple power semiconductor arrangements according to claim 1, wherein the base plate of the power semiconductor arrangements is a common base plate.

14. The power semiconductor module according to claim 13, wherein:
the power semiconductor module comprises a housing;
an electrically conducting lid forms a top side of the housing and provides a first contact of the power semiconductor module;
the common base plate forms a base of the housing and provides a second contact of the power semiconductor module;
the presspin of each power semiconductor arrangement is respectively arranged between the power semiconductor device of the power semiconductor arrangement and the lid; and
the power semiconductor devices are in electric contact with the lid.

15. A module assembly comprising multiple power semiconductor modules according to claim 13,
wherein the power semiconductor modules are arranged side by side to each other with electric connections between adjacent semiconductor modules.

16. The module assembly according to claim 15, wherein the base plates of the power semiconductor modules are electrically connected to each other.

17. The module assembly according to claim 15, wherein the module assembly comprises a housing, and wherein:
the common base plates of the power semiconductor modules extend through a base of the housing; and
an electrically conducting lid forms a top side of the housing and provides a common contact for the power semiconductor modules.

18. The semiconductor arrangement according to claim 1, wherein the mounting base is made of one of copper and an alloy based on copper.

19. The semiconductor arrangement according to claim 18, wherein the mounting base supports the formation of a short-circuit failure mode in case of failure of the power semiconductor device.

20. The semiconductor arrangement according to claim 19, comprising:
a platelet arranged between the power semiconductor device and the presspin,
wherein the platelet is made of at least one of copper, aluminum, silver, gold magnesium, and an alloy thereof.

21. The semiconductor arrangement according to claim 4, wherein the mounting base is provided as a mounting plate with a surface area bigger than the surface area of the semiconductor device.

22. The semiconductor arrangement according to claim 4, wherein the mounting base is provided as a mounting layer extending over the molybdenum layer.

23. The semiconductor arrangement according to claim 7, wherein the mounting layer is laminated to the molybdenum layer.

24. The semiconductor arrangement according to claim 8, wherein the base plate comprises a base layer, which is provided on the molybdenum layer opposite to the mounting layer, and
wherein the base layer has a thermal expansion coefficient essentially equal to the thermal expansion coefficient of the mounting layer.

25. The semiconductor arrangement according to claim 24, wherein the base layer and the mounting layer are provided as identical layers.

26. The semiconductor arrangement according to claim 7, wherein the thickness of the molybdenum layer is at least 3 times higher than the thickness of the mounting layer.

27. The semiconductor arrangement according to claim 11, wherein the thickness of the molybdenum layer is 3 to 10 times higher than the thickness of the mounting plate.

28. The semiconductor arrangement according to claim 11, wherein the thickness of the molybdenum layer is 5 to 6 times higher than the thickness of the mounting plate.

29. The semiconductor arrangement according to claim 9, wherein the thickness of the molybdenum layer is between 1 mm and 10 mm.

30. The module assembly according to claim 15, wherein the module assembly comprises a power semiconductor module assembly.

31. A module assembly comprising multiple power semiconductor modules according to claim 14,
wherein the power semiconductor modules are arranged side by side to each other with electric connections between adjacent semiconductor modules.

32. The module assembly according to claim 31, wherein the base plates of the power semiconductor modules are electrically connected to each other.

33. The module assembly according to claim 31, wherein the module assembly comprises a housing, and wherein:
the common base plates of the power semiconductor modules extend through a base of the housing; and
an electrically conducting lid forms a top side of the housing and provides a common contact for the power semiconductor modules.

34. The module assembly according to claim 16, wherein the module assembly comprises a housing, and wherein:
the common base plates of the power semiconductor modules extend through a base of the housing; and
an electrically conducting lid forms a top side of the housing and provides a common contact for the power semiconductor modules.
